(19) United States
(12) Patent Application Publication
(10) Pub. No.: US 2022/0045040 A1
(43) Pub. Date: Feb. 10, 2022

(54) OPTOELECTRONIC DEVICE FOR ACQUIRING MULTI-VIEWPOINT IMAGES AND/OR DISPLAYING MULTI-VIEWPOINT IMAGES

(71) Applicant: Parc d'Entreprises Sud Galaxie, Echirolles (FR)

(72) Inventors: Ivan-Christophe Robin, Grenoble (FR); Frédéric Mercier, Saint Nicolas De Macherin (FR); Matthieu Charbonnier, Fontaine (FR); Olivier Jeannin, Grenoble (FR)

(73) Assignee: Parc d'Entreprises Sud Galaxie, Echirolles (FR)

(21) Appl. No.: 17/312,346

(22) PCT Filed: Dec. 17, 2019
(86) PCT No.: PCT/FR2019/053134

§ 371 Date: Jun. 9, 2021

(30) Foreign Application Priority Data
Dec. 18, 2018 (FR) 1873198

(51) Int. Cl. H01L 25/16; H01L 27/146; H01L 33/58; H01L 33/00

(52) U.S. Cl. CPC H01L 25/167; H01L 27/14627; H01L 33/005; H01L 27/14687; H01L 33/58

(57) ABSTRACT

An optoelectronic multiscopic image display and/or capture device, including a support, an array of optoelectronic circuits resting on the support, and lenses covering the optoelectronic circuits. Each optoelectronic circuit includes a number N of photosensors capable of capturing a pixel or pixels of an image of a scene according to different viewpoints and/or number N of display circuits capable of displaying a pixel or pixels of an image of a scene according to the different viewpoints, N being a natural number greater than or equal to 3.

The present patent application claims the priority benefit of French patent application FR18/73198 which is herein incorporated by reference.

### TECHNICAL BACKGROUND

The present disclosure generally concerns an optoelectronic device for the capture of images from a plurality of viewpoints and/or the display of images according to a plurality of viewpoints.

### PRIOR ART

An example of a device of multiscopic capture of a film, that is, with a plurality of viewpoints, comprises an array of microlenses arranged in front of a single camera comprising an array of photosensors. Images of a scene according to different viewpoints are then captured in interlaced fashion.

An example of a device of multiscopic display of a film comprises interlaced display pixel arrays. Images of a scene from different viewpoints are then displayed in interlaced fashion.

A disadvantage of known multiscopic image capture devices and multiscopic image display devices is that the electric connection of the display pixels enabling to display interlaced images or the electric connection of the photosensors enabling to capture interlaced images, corresponding to different viewing angles, becomes complex as soon as the resolution of the images to be captured or to be displayed is significant.

Another disadvantage of multiscopic image capture devices and of multiscopic image display devices is that a processing of the images captured by the multiscopic image capture device is generally necessary to obtain images in a format adapted for their display on a multiscopic image display device.

### SUMMARY

An embodiment overcomes all or part of the disadvantages of optoelectronic device for multiscopic image capture and/or multiscopic image display.

An embodiment provides an optoelectronic device for the multiscopic capture of images and/or the multiscopic display of images, for which the electric connection of the image pixels enabling to display interlaced images, or the electric connection of the photosensors enabling to acquire interlaced images, is simple.

An embodiment provides an optoelectronic multiscopic image display and/or capture device, comprising a support, an array of optoelectronic circuits resting on the support, and lenses covering the optoelectronic circuits, each optoelectronic circuit comprising a number N of photosensors capable of capturing a pixel or pixels of an image of a scene according to different viewpoints and/or the number N of display circuits capable of displaying a pixel or pixels of an image of a scene according to the different viewpoints, N being a natural number greater than or equal to 3.

According to an embodiment, each optoelectronic circuit comprises the number N of photosensors capable of capturing a pixel of an image of a scene according to different viewpoints and the number N of display circuits capable of displaying a pixel of an image of a scene according to the different viewpoints.

According to an embodiment, the photosensors and/or the display circuits are arranged in an array.

According to an embodiment, each optoelectronic circuit comprises the N display circuits and an integrated circuit attached to the support, the N display circuits being attached to the integrated circuit, on the side of the integrated circuit opposite to the support.

According to an embodiment, the integrated circuit comprises the N photosensors.

According to an embodiment, each display circuit comprises at least one light-emitting diode.

According to an embodiment, each photosensor comprises at least one photodiode.

According to an embodiment, each optoelectronic circuit is connected to less than 10 electrically-conductive tracks.

An embodiment also provides the method of manufacturing the optoelectronic device such as previously defined.

According to an embodiment, each optoelectronic circuit comprises the N display circuits and an integrated circuit attached to the support, the N display circuits being attached to the integrated circuit, on the side of the integrated circuit opposite to the support, the method comprising the successive steps of:
a) forming a first wafer comprising a plurality of copies of the integrated circuit and forming a second wafer comprising a plurality of copies of the display circuit;
b) attaching the second wafer to the first wafer;
c) separating the display circuits in the second wafer; and
d) separating the integrated circuits in the first wafer.

According to an embodiment, step d) is preceded by a step e) of attaching the display circuits to a handle.

According to an embodiment, the method comprises, between steps e) and d), a step of thinning the first wafer.

An embodiment also provides the use of an optoelectronic device such as previously defined, comprising the provision by each optoelectronic circuit of first data representative of the image pixels captured by the N photosensors of said optoelectronic circuit and/or the provision to each optoelectronic circuit of second data representative of the pixels of the image to be displayed by the N display circuits of said optoelectronic circuit.

According to an embodiment, the optoelectronic circuits are arranged in rows and in columns and, for each column, at least one of the optoelectronic circuits of the column is capable of receiving signals and of at least partly transmitting said signals to another optoelectronic circuit of the column.

### BRIEF DESCRIPTION OF THE DRAWINGS

FIG. 1 is a partial simplified cross-section view of an embodiment of multiscopic image capture and projection device;

FIG. 2 is a partial simplified top view of the optoelectronic device shown in FIG. 1;

FIG. 3 is a simplified view illustrating the operating principle of a multiscopic image display screen;

FIG. 4 is a partial simplified cross-section view of a more detailed embodiment of the multiscopic image capture and projection device shown in FIGS. 1 and 2;

FIG. 5 is a partial simplified cross-section view of another more detailed embodiment of the multiscopic image capture and projection device shown in FIGS. 1 and 2;

FIG. 6 is a partial simplified cross-section view of another more detailed embodiment of the multiscopic image capture and projection device shown in FIGS. 1 and 2;

FIG. 7 shows lateral partial simplified cross-section views 7A to 7E of structures obtained at successive steps of an embodiment of a method of manufacturing the optoelectronic device shown in FIG. 4;

FIG. 8 shows lateral partial simplified cross-section views 8A to 8D of structures obtained at subsequent successive steps of an embodiment of a method of manufacturing the optoelectronic device shown in FIG. 4;

FIG. 9 shows lateral partial simplified cross-section views 9A to 9C of structures obtained at subsequent successive steps of an embodiment of a method of manufacturing the optoelectronic device shown in FIG. 4;

FIG. 10 is a diagram illustrating an embodiment of the electric connections between the pixels of the optoelectronic device shown in FIGS. 1 and 2;

FIG. 11 is a diagram illustrating an embodiment of a method of controlling a pixel of the optoelectronic device shown in FIG. 10;

FIG. 12 is a diagram illustrating another embodiment of a method of controlling a pixel of the optoelectronic device shown in FIG. 10;

FIG. 13 is a diagram illustrating another embodiment of a method of controlling a pixel of the optoelectronic device shown in FIG. 10;

FIG. 14 shows in the form of a block diagram an embodiment of a pixel of the device shown in FIGS. 1 and 2; and

FIG. 15 illustrates an embodiment of a method of controlling pixels of the device shown in FIGS. 1 and 2.

### DESCRIPTION OF THE EMBODIMENTS

The same elements have been designated with the same reference numerals in the different drawings. In particular, the structural and/or functional elements common to the different embodiments may be designated with the same reference numerals and may have identical structural, dimensional, and material properties.

For clarity, only those steps and elements which are useful to the understanding of the described embodiments have been shown and are detailed. In particular, the structure of a light-emitting diode is well known by those skilled in the art and has not been described in detail.

Unless indicated otherwise, the term “connected” is used to designate a direct electrical connection between circuit elements with no intermediate elements other than conductors, whereas the term “coupled” is used to designate an electrical connection between circuit elements that may be direct, or may be via one or more other elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use.

Unless indicated otherwise, the terms “about”, “approximately”, “substantially”, and “in the order of” are used herein to designate a tolerance of plus or minus 10%, preferably of plus or minus 5%, of the value in question. Further, the “active area” or “active layer” of a light-emitting diode designates the region of the light-emitting diode from which most of the electromagnetic radiation provided by the light-emitting diode is emitted. Further, a signal which alternates between a first constant state, for example, a low state, noted “0”, and a second constant state, for example, a high state, noted “1”, is called a “binary signal”. The high and low states of different binary signals of a same electronic circuit may be different. In particular, the binary signals may correspond to voltages or to currents which may not be perfectly constant in the high or low state. In the following description, a transparent layer is a layer which is transparent to the radiations emitted by the optoelectronic device or to the radiations detected by the optoelectronic device.

A pixel of an image corresponds to the unit element of the image displayed by a display optoelectronic device. When the optoelectronic device is a color image display screen, it generally comprises, for the display of each pixel of the image, at least three components, also called display sub-pixels, which each emit a light radiation substantially in a single color (for example, red, green, and blue). The superposition of the radiations emitted by the three display sub-pixels provides the observer with the colored sensation corresponding to the pixel of the displayed image. In this case, the assembly formed by the three display sub-pixels used to display a pixel of an image is called display pixel of the optoelectronic device.

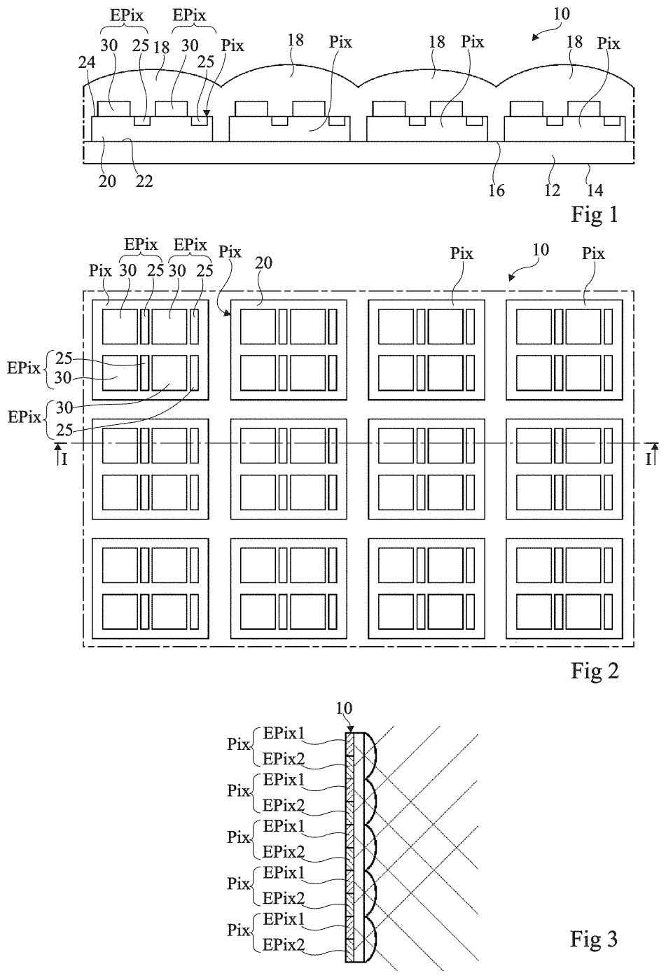

FIGS. 1 and 2 show an embodiment of an optoelectronic multiscopic image capture and display device 10 comprising display and capture pixels, four display and capture pixels being shown in FIG. 1 and twelve display and capture pixels being shown in FIG. 2. FIG. 1 is a cross-section of FIG. 2 along line II-II and FIG. 2 is a top view of FIG. 1.

Device 10 comprises, from bottom to top in FIG. 1:
a support 12 comprising opposite lower and upper surfaces 14, 16, preferably parallel;
display and capture pixels Pix, also called display and capture pixel circuits hereafter, resting on upper surface 16, for example distributed in rows and in columns, three rows and four columns being shown in FIG. 2; and
microlenses 18, not shown in FIG. 2, covering pixels Pix.

Microlenses 18 may be cylindrical or spherical microlenses, each microlens 18 for example covering a pixel column Pix, two adjacent pixel columns Pix, or more than two adjacent pixel columns Pix. Preferably, each microlens 18 is a cylindrical lens covering a pixel column Pix or two adjacent pixel columns Pix. As a variation, each microlens 18 may only cover a group of adjacent pixels Pix of a same column, of two adjacent columns, or of more than two adjacent columns of pixels. According to an embodiment, each microlens 18 covers a single pixel Pix.

Each pixel Pix comprises, from bottom to top in FIG. 1:
a first optoelectronic circuit 20, called control and capture circuit hereafter, comprising a lower surface 22 facing support 12 and an upper surface 24 opposite to lower surface 22, surfaces 22, 24 being preferably parallel, control and capture circuit 20 comprising photosensors 25 on the upper surface side, each photosensor 25 for example comprising photodiodes or photoresistors, four photosensors 25 being shown per pixel Pix in FIG. 2; and
second optoelectronic circuits 30, called display circuits hereafter, attached to upper surface 24 of control and capture circuit 20, four display pixels 30 being shown per pixel Pix in FIG. 2, each display circuit 30 comprising light sources, not shown, it being possible for display circuits 30 to be integrated in a single optoelectronic circuit.

According to an embodiment, each pixel Pix comprises an array of elementary pixels EPix, each elementary pixel EPix comprising a display circuit 30 for the display of a pixel of an image of a scene according to a given viewpoint and a photosensor 25 for the acquisition of the pixel of an image of a scene according to the same viewpoint. For each pixel Pix, the elementary pixels EPix of pixel Pix are associated with different viewpoints. According to an embodiment, each pixel Pix comprises an array of at least two rows and of at least two columns of elementary pixels EPix, preferably of at least five columns and of at least five rows of elementary pixels.

FIG. 3 is a top view very schematically illustrating the operating principle of optoelectronic device 10 for the automultiscopic display of images. Images of a scene according to different viewpoints are displayed in interlaced fashion by optoelectronic device 10. FIG. 3 schematically shows a row of pixels Pix where the display circuits of first elementary pixels EPix1, hatched in a first direction, display pixels of an image according to a first viewpoint and display circuits of second elementary pixels EPix2, hatched in a second direction, display pixels of an image according to a second viewpoint. Microlenses 18 are configured and arranged so that the light rays emitted by the display circuits of the first elementary pixels EPix1 only reach an observer's left eye and that the light rays emitted by the display circuits of the second elementary pixels EPix2 only reach an observer's right eye, when the observer is at a given location with respect to optoelectronic device 10. A three-dimensional effect is then perceived by the observer. In practice, images corresponding to more than two viewpoints may be simultaneously displayed in interlaced fashion so that the observer keeps on perceiving three-dimensional images while moving with respect to optoelectronic device 10.

During a step of capture of images of a scene, the photosensors of the elementary pixels of pixels Pix are activated. The layout and the configuration of microlenses 18 results in that images of the same scene according to different viewpoints are simultaneously captured by the photosensors of the elementary pixels of pixels Pix. As an example, in relation with FIG. 3, the light rays detected by the photosensors of the first elementary pixels EPix1 correspond to pixels of an image of a scene according to a first viewpoint and the light rays detected by the photosensors of the second elementary pixels EPix2 correspond to pixels of an image of the scene according to a second viewpoint.

An advantage of optoelectronic device 10 is that is images captured in multiscopy by optoelectronic device 10 may be simply displayed by the same optoelectronic device 10 or by an optoelectronic device of same structure. Indeed, there is no processing to be provided for the display, by optoelectronic device 10, of the images captured in multiscopy by the same optoelectronic device 10, and the signals delivered by the elementary pixels of each pixel for the multiscopic image capture may be directly delivered to the same elementary pixels for a multiscopic image display. Without using exactly the same device, the data captured by device 10 may be displayed by any screen operating by displaying different viewing angles.

Another advantage of optoelectronic device 10 is that the field of view capable of being captured by the optoelectronic device may be large.

According to an embodiment, during the multiscopic display of a film, photosensors 25 may further be used to determine the position of the eyes of the observer who is looking at the image displayed in multiscopy. This may be used to adapt the images displayed in multiscopy by taking into account the position of the observer's eyes, for example, to only activate the display circuits 30 emitting rays towards the observer's eyes. This enables to limit the stream of data to be processed/sent, and thus decreases the electric power consumption.

According to an embodiment, when the images captured in multiscopy by device 10 are to be displayed on a display screen which is not adapted to multiscopic image display, an image with no relief can be displayed, with the possibility of adjusting the image focusing point.

According to an embodiment, each display circuit 30 comprises at least one light-emitting diode. In the case where each display circuit 30 comprises two light-emitting diodes or more than two light-emitting diodes, the active areas of all the light-emitting diodes of display circuit 30 preferably emit a light radiation substantially at the same wavelength.

Each light-emitting diode may correspond to a so-called two-dimensional light-emitting diode comprising a stack of substantially planar semiconductor layers including the active area. Each light-emitting diode may comprise at least one three-dimensional light-emitting diode having a radial structure comprising a semiconductor shell covering a three-dimensional semiconductor element, particularly a microwire, a nanowire, a cone, a frustum, a pyramid, or a truncated pyramid, the shell being formed of a stack of non-planar semiconductor layers including the active area. Examples of such light-emitting diodes are described in patent application US2014/0077151 and US2016/0218240. Each light-emitting diode may comprise at least one three-dimensional light-emitting diode having an axial structure where the shell is located in the axial extension of the semiconductor element.

For each pixel Pix, the display circuits 30, which may be integrated in a single display circuit, may be attached to control and capture circuit 20 by direct bonding, for example, by heterogeneous molecular bonding. Such a connection ensures the mechanical connection between each display circuit 30 and control and capture circuit 20 and further ensures the electric connection of the light-emitting diode or of the light-emitting diodes of display circuit 30 to control and capture circuit 20. As a variation, display circuit or display circuits 30 may be attached to control and capture circuit 20 by a “flip-chip”-type connection. Fusible conductive elements, for example, solder balls or indium balls, may couple each display circuit 30 to control and capture circuit 20.

According to an embodiment, each elementary pixel EPix is capable of emitting a first radiation at a first wavelength and a second radiation at a second wavelength. According to an embodiment, each elementary pixel EPix is further capable of emitting a third radiation at a third wavelength. The first, second, and third wavelengths may be different. According to an embodiment, the first wavelength corresponds to blue light and is within the range from 430 nm to 490 nm. According to an embodiment, the second wavelength corresponds to green light and is within the range from 510 nm to 570 nm. According to an embodiment, the third wavelength corresponds to red light and is within the range from 600 nm to 720 nm.

According to an embodiment, each elementary pixel EPix is further capable of emitting a fourth radiation at a fourth wavelength. The first, second, third, and fourth wavelengths may be different. According to an embodiment, the fourth wavelength corresponds to yellow light and is in the range from 570 nm to 600 nm. According to another embodiment, the fourth radiation corresponds to a radiation in close infrared, particularly at a wavelength between 700 nm and 980 nm, to an ultraviolet radiation, or to white light.

According to an embodiment, each elementary pixel EPix is capable of detecting a fifth radiation at a fifth wavelength and a sixth radiation at a sixth wavelength. According to an embodiment, each elementary pixel EPix is further capable of detecting a seventh radiation at a seventh wavelength. The fifth, sixth, and seventh wavelengths may be different. According to an embodiment, the fifth wavelength corresponds to the first previously-described wavelength, that is, to blue light in the range from 430 nm to 490 nm. According to an embodiment, the sixth wavelength corresponds to the second previously-described wavelength, that is, to green light in the range from 510 nm to 570 nm. According to an embodiment, the seventh wavelength corresponds to the third previously-described wavelength, that is, to red light in the range from 600 nm to 720 nm.

According to an embodiment, each elementary pixel EPix is further capable of detecting an eighth radiation at an eighth wavelength. The fifth, sixth, seventh, and eighth wavelengths may be different. According to an embodiment, the eighth wavelength corresponds to the fourth previously-described wavelength, that is, to yellow light in the range from 570 nm to 600 nm, to a radiation in near infrared, particularly at a wavelength between 700 nm and 980 nm, or to an ultraviolet radiation.

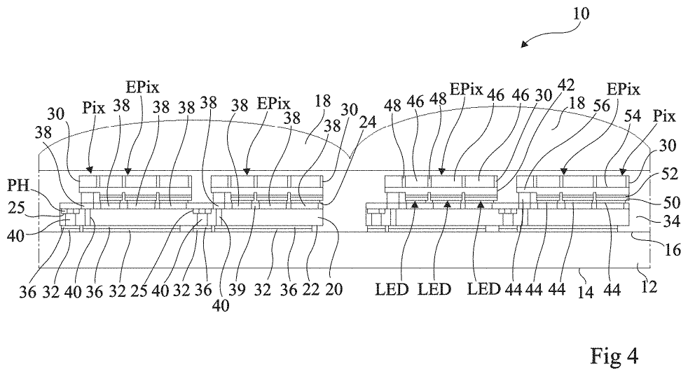

FIG. 4 is a partial simplified cross-section view of a more detailed embodiment of the multiscopic image capture and display device 10 shown in FIGS. 1 and 2. In the present embodiment, device 10 comprises, from bottom to top in FIG. 4:
support 12;
electrodes 32 made of an electrically-conductive material resting on upper surface 16, four electrodes 32 per pixel Pix being shown in FIG. 4;
pixels Pix, resting on electrodes 32 and in contact with electrodes 32, two pixels Pix being shown in FIG. 4, each pixel Pix comprising two elementary pixels EPix;
an electrically-insulating encapsulation layer 34 covering support 12 between pixels Pix and covering pixels Pix; and
microlenses 18.

Generally, each pixel Pix may comprise more than two elementary pixels EPix. According to an embodiment, elementary pixels EPix have substantially the same structure, each elementary pixel EPix comprising a display circuit 30 and a portion of control and capture circuit 20 particularly comprising a photosensor 25.

For each pixel Pix, the lower surface 22 of control and capture circuit 20 is attached to electrodes 32 and is for example delimited by electrically-conductive pads 36 electrically coupled to electrodes 32. Control and capture circuit 20 further comprises electrically-conductive pads 38 on upper surface side 24. Conductive pads 38 may be laterally separated by an electrically-insulating layer 39. Control and capture circuit 20 further comprises, for each elementary pixel EPix, photosensor 25 on the side of upper surface 24, each photosensor 25 preferably comprising at least three photodiodes PH. Control and capture circuit 20 further comprises transistors, not shown, on the side of upper surface 24. Control and capture circuit 20 comprises through conductive vias 40 which couple conductive pads 36 to semiconductor regions of the control and capture circuit located on the side of upper surface 24 or to some of pads 38. As an example, FIG. 4 shows, for each elementary pixel EPix, a first via 40 coupling one of pads 36 to photodiodes PH and a second via 40 coupling another pad 36 to one of pads 38.

For each elementary pixel EPix, display circuit 30 is attached to upper surface 24 of the control and capture circuit 20 of pixel Pix. Each display circuit 30 comprises a stack 42 of semiconductor layers forming light-emitting diodes LED, preferably at least three light-emitting diodes. Each display circuit 30 is electrically coupled to control and capture circuit 20 by electrically-conductive pads 44 in contact with conductive pads 38. Each display circuit 30 comprises photoluminescent blocks 46 covering light-emitting diodes LED on the side opposite to control and capture circuit 20 and laterally separated by walls 48. Preferably, each photoluminescent block 46 is located opposite one of light-emitting diodes LED. In FIG. 4, the light-emitting diodes LED and the photoluminescent blocks 46 of each elementary pixel EPix have been shown in aligned fashion. It should however be clear that the layout of light-emitting diodes LED and of photoluminescent blocks 46 may be different. As an example, each display circuit 30 may comprise four light-emitting diodes distributed, in top view, at the corners of a square.

In the present embodiment, each light-emitting diode LED corresponds to a so-called two-dimensional light-emitting diode comprising a stack of substantially planar semiconductor layers, including the active area. According to an embodiment, all the light-emitting diodes LED of an elementary pixel EPix preferably emit a light radiation substantially at the same wavelength.

More particularly, stack 42 comprises, for each light-emitting diode LED, a doped semiconductor layer 50 of a first conductivity type, for example, P-type doped, in contact with a conductive pad 44, an active layer 52 in contact with semiconductor layer 50, and a doped semiconductor layer 54 of a second conductivity type opposite to the first conductivity type, for example, N-type doped, in contact with active layer 52. Display circuit 30 further comprises a semiconductor layer 56 in contact with the semiconductor layer 52 of all the light-emitting diodes LED and having walls 48 and photoluminescent blocks 46 resting thereon. Semiconductor layer 56 is, for example, made of the same material as semiconductor layer 54. According to an embodiment, each display circuit 30 comprises, for each light-emitting diode LED, a conductive pad 44 coupling the semiconductor layer 50 of light-emitting diode LED to control and capture circuit 20, and at least one conductive pad 44 coupling semiconductor layer 56 directly to control and capture circuit 20.

For each light-emitting diode LED, active layer 52 may comprise confinement means. As an example, active layer 52 may comprise a single quantum well. It then comprises a semiconductor material different from the semiconductor material forming semiconductor layers 50 and 54 and having a bandgap smaller than that of the material forming semiconductor layers 50 and 54. Active layer 52 may comprise multiple quantum wells. It then comprises a stack of semiconductor layers forming an alternation of quantum wells and of barrier layers.

According to an embodiment, each photoluminescent block 46 is located opposite one of the light-emitting diodes LED. Each photoluminescent block 46 comprises luminophores capable, when they are excited by the light emitted by the associated light-emitting diode LED, of emitting light at a wavelength different from the wavelength of the light emitted by the associated light-emitting diode LED. According to an embodiment, each pixel Pix comprises at least two types of photoluminescent blocks 46. The photoluminescent block 46 of the first type is capable of converting the radiation supplied by light-emitting diodes LED to emit the radiation at the first wavelength, and the photoluminescent block 46 of the second type is capable of converting the radiation supplied by light-emitting diodes LED to emit the radiation at the second wavelength. According to an embodiment, each pixel Pix comprises at least three types of photoluminescent blocks 46, the photoluminescent block 46 of the third type being capable of converting the radiation supplied by the light-emitting diodes LED to emit the third radiation at the third wavelength.

The control and capture circuit 20 of a pixel Pix may comprises electronic components, including photodiodes PH, and particularly transistors, not shown, used to control the light-emitting diodes LED and the photodiodes PH of the elementary pixels EPix of pixel Pix. Each control and capture circuit 20 may comprises a semiconductor substrate inside and/or on top of which the electronic components are formed. Lower surface 22 of control and capture circuit 20 may then correspond to the back side of the substrate opposite to the front side 24 of the substrate on the side of which the electronic components are formed. The semiconductor substrate is, for example, a substrate made of silicon, particularly, of single-crystal silicon. The structure of photodiodes is well known by those skilled in the art and is not described in further detail hereafter.

According to an embodiment, display circuits 30 only comprise light-emitting diodes and elements of connection of the light-emitting diodes, and control and capture circuits 20 comprise all the electronic components necessary to control the light-emitting diodes of display circuits 30. According to another embodiment, display circuits 30 may also comprise other electronic components in addition to the light-emitting diodes.

Optoelectronic device 10 may comprise from 10 to 10⁹ pixels Pix. Each pixel Pix may occupy in top view a surface area in the range from 1 μm² to 100 mm². The thickness of each pixel Pix may be in the range from 1 μm to 6 mm. The thickness of each control and capture circuit 20 may be in the range from 0.5 μm to 3,000 μm. The thickness of each display circuit 30 may be in the range from 0.2 μm to 3,000 μm.

In the present embodiment, all the electric connections of pixel Pix to the outside are formed on the lower surface side 22 of control and capture circuit 20. Thereby, the number of electrodes 32 depends on the number of electric connections to the outside necessary for the operation of pixel Pix.

Microlenses 18 may correspond to cylindrical lenses, for example, planoconvex lenses, or to spherical planoconvex lenses. According to an embodiment, pixels Pix may be arranged so that each pixel Pix is substantially located in the focal plane of the microlens 18 associated therewith. According to an embodiment, each pixel Pix is substantially centered at the focal point of the microlens 18 associated therewith. As a variation, the relative position between pixel Pix and the microlens 18 associated therewith may vary according to the position of the pixel in the pixel array of the optoelectronic device. In particular, even if pixel Pix is arranged substantially in the focal plane of the microlens 18 associated therewith, an interval between the position of pixel Pix and the focal point of microlens 18 may be provided, this interval for example increasing as the distance to the center of optoelectronic device 10 increases. This interval will enable to emit/collect according to different angles.

Support 12 may be made of an electrically-insulating material, for example, comprising a polymer, particularly an epoxy resin, and in particular the FR4 material used for the manufacturing of printed circuits, or of a metallic material, for example, aluminum. The thickness of support 12 may be in the range from 10 μm to 10 mm.

Each electrode 32 preferably corresponds to a metal strip, for example, made of aluminum, silver, copper, or zinc. The thickness of each electrode 32 may be in the range from 0.5 μm to 1,000 μm.

Insulating layer 39 may be made of a dielectric material, for example, of silicon oxide (SiO₂), of silicon nitride (SiₓN_{y}, where x is approximately equal to 3 and y is approximately equal to 4, for example, Si₃N₄), of silicon oxynitride (SiOₓN_{y}, where x may be approximately equal to ½ and y may be approximately equal to 1, for example, Si₂ON₂), of aluminum oxide (Al₂O₃), or of hafnium oxide (HfO₂). The thickness of insulating layer 39 may be in the range from 0.2 μm to 1,000 μm.

Each conductive pad 36, 38, 44 may be at least partly made of a material selected from the group for example comprising copper, titanium, nickel, gold, tin, aluminum, and alloys of at least two of these compounds.

Semiconductor layers 50, 54, 56 and the layers forming active layer 52 are at least partly made of at least one semiconductor material. The semiconductor material is selected from the group comprising III-V compounds, for example, a III-N compound, II-VI compounds, or group-IV semiconductors or compounds. Examples of group-III elements comprise gallium (Ga), indium (In), or aluminum (Al). Examples of III-N compounds are GaN, AlN, InN, InGaN, AlGaN, or AlInGaN. Other group-V elements may also be used, for example, phosphorus or arsenic. Examples of group-II elements comprise group-IIA elements, particularly beryllium (Be) and magnesium (Mg), and group-IIB elements, particularly zinc (Zn), cadmium (Cd), and mercury (Hg). Examples of group-VI elements comprise group-VIA elements, particularly oxygen (O) and tellurium (Te). Examples of II-VI compounds are ZnO, ZnMgO, CdZnO, CdZnMgO, CdHgTe, CdTe, or HgTe. Examples of group-IV semiconductor materials are silicon (Si), carbon (C), germanium (Ge), silicon carbide alloys (SiC), silicon-germanium alloys (SiGe), or germanium carbide alloys (GeC).

According to an embodiment, each photoluminescent block 46 comprises particles of at least one photoluminescent material. An example of a photoluminescent material is yttrium aluminum garnet (YAG) activated by the trivalent cerium ion, also called YAG:Ce or YAG:Ce³⁺. The average size of the particles of conventional photoluminescent materials is generally greater than 5 μm.

According to an embodiment, each photoluminescent block 46 comprises a matrix having nanometer-range monocrystalline particles of a semiconductor material, also called semiconductor nanocrystals or nano-luminophore particles hereafter, dispersed therein. The internal quantum efficiency QYᵢₙₜ of a photoluminescent material is equal to the ratio of the number of emitted photons to the number of photons absorbed by the photoluminescent substance. The internal quantum efficiency QYᵢₙₜ of the semiconductor nanocrystals is greater than 5%, preferably greater than 10%, more preferably greater than 20%. According to an embodiment, the average size of the nanocrystals is in the range from 0.5 nm to 1,000 nm, preferably from 0.5 nm to 500 nm, more preferably from 1 nm to 100 nm, particularly from 2 nm to 30 nm. For dimensions smaller than 50 nm, the photoconversion properties of semiconductor nanocrystals essentially depend on quantum confinement phenomena. The semiconductor nanocrystals then correspond to quantum dots.

According to an embodiment, the semiconductor material of the semiconductor crystals is selected from the group comprising cadmium selenide (CdSe), indium phosphide (InP), cadmium sulfide (CdS), zinc sulfide (ZnS), zinc selenide (ZnSe), cadmium telluride (CdTe), zinc telluride (ZnTe), cadmium oxide (CdO), zinc cadmium oxide (ZnCdO), cadmium zinc sulfide (CdZnS), cadmium zinc selenide (CdZnSe), silver indium sulfide (AgInS₂), perovskites of PbScX₃ type where X is a halogen atom, particularly iodine (I), bromine (Br), or chlorine (Cl), and a mixture of at least two of these compounds. According to an embodiment, the semiconductor material of the semiconductor nanocrystals is selected from the materials mentioned in Le Blevenec et al.'s publication in Physica Status Solidi (RRL)—Rapid Research Letters Volume 8, No. 4, pages 349-352, April 2014.

According to an embodiment, the dimensions of the semiconductor nanocrystals are selected according to the desired wavelength of the radiation emitted by the semiconductor nanocrystals. As an example, CdSe nanocrystals having an average size in the order of 3.6 nm are capable of converting blue light into red light and CdSe nanocrystals having an average size in the order of 1.3 nm are capable of converting blue light into green light. According to another embodiment, the composition of the semiconductor nanocrystals is selected according to the desired wavelength of the radiation emitted by the semiconductor nanocrystals.

The matrix is made of an at least partly transparent material. The matrix is for example made of silica. The matrix is for example made of any at least partly transparent polymer, particularly of silicone or of polylactic acid (PLA). The matrix may be made of an at least partly transparent polymer used with three-dimensional printers, such as PLA. According to an embodiment, the matrix contains from 2% to 90%, preferably from 10 wt. % to 60 wt. %, of nanocrystals, for example, approximately 30 wt. % of nanocrystals.

The thickness of photoluminescent blocks 46 depends on the nanocrystal concentration and on the type of nanocrystals used. The height of photoluminescent blocks 46 is preferably smaller than or equal to the height of walls 48. In top view, the area of each photoluminescent block 46 may correspond to the area of a square having a side length from 1 μm to 100 μm, preferably from 3 μm to 15 μm.

According to an embodiment, walls 48 are at least partly made of at least one conductive or insulating semiconductor material. The semiconductor or metal conductor material may be silicon, germanium, silicon carbide, a III-V compound, a II-VI compound, steel, iron, copper, aluminum, tungsten, titanium, hafnium, zirconium, silver, rhodium, or a combination of at least two of these compounds. According to an embodiment, walls 48 are made of a reflective material. Preferably, walls 48 are made of a semiconductor material compatible with the manufacturing methods implemented in microelectronics. Walls 48 may be heavily-doped, lightly-doped, or non-doped. Preferably, walls 48 are made of single-crystal silicon. The height of walls 48, measured along a direction perpendicular to surface 22, is in the range from 300 nm to 200 μm, preferably from 5 μm to 30 μm. The thickness of walls 48, measured along a direction parallel to surface 22, is in the range from 100 nm to 50 μm, preferably from 0.5 μm to 10 μm. According to an embodiment, walls 48 may be made of a reflective material or covered with a coating which is reflective at the wavelength of the radiation emitted by photoluminescent blocks 46 and/or light-emitting diodes LED. Preferably, walls 48 surround photoluminescent blocks 46. Walls 48 then decrease the crosstalk between adjacent photoluminescent blocks 46.

Encapsulation layer 34 may be made of an at least partially transparent insulating material. Encapsulation layer 34 may be made of an at least partially transparent inorganic material. As an example, the inorganic material is selected from the group comprising silicon oxides of SiOₓ type, where x is a real number between 1 and 2 or SiO_{y}N_{z}, where y and z are real numbers between 0 and 1, and aluminum oxides, for example, Al₂O₃. Encapsulation layer 34 may be made of an at least partially transparent organic material. As an example, encapsulation layer 34 is a silicone polymer, an epoxide polymer, an acrylic polymer, or a polycarbonate.

Microlenses 18 may be made of silicon oxide, of silicone, of poly(methyl methacrylate) (PMMA), or of transparent resin. The maximum thickness of each microlens 18 may be in the range from 10 μm to 10 mm. The width of each microlens 18 may vary from 10 μm to 10 mm.

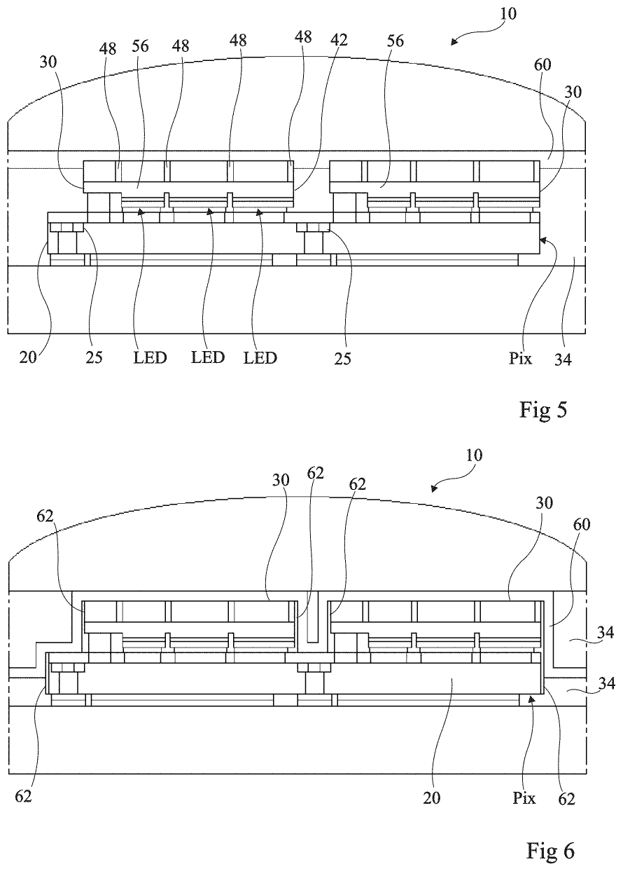

FIG. 5 is a side view of another more detailed embodiment of optoelectronic device 10. In this embodiment, optoelectronic device 10 comprises all the elements of the embodiment previously described in relation with FIG. 4, with the difference that, for each display circuit 30, the polarization of semiconductor layer 56 is performed via walls 48. In the present embodiment, encapsulation layer 34 extends between pixels Pix but does not completely cover pixels Pix. Optoelectronic device 10 further comprises electrically-conductive strips 60, a single strip being shown in FIG. 5, forming electrodes at least partially transparent to the radiations emitted by light-emitting diodes LED and covering pixels Pix and encapsulation layer 34 between pixels Pix. As an example, each conductive strip 60 is in contact with the pixels Pix of a same column or of a same row. For each display circuit 30, walls 48 are electrically conductive. Walls 48 are in contact with stack 42 and in contact with the conductive strip 60 covering pixel Pix. This enables to polarize the semiconductor layer 56 of stack 42, and the semiconductor regions of control and capture circuit 20, electrically coupled to semiconductor layer 56 by a pad 44, are electrically polarized by the conductive strip 60 covering pixel Pix.

Each conductive strip 60 is capable of giving way to the electromagnetic radiation emitted by display circuits 30 and to the electromagnetic radiation detected by photosensors 25. The material forming each conductive strip 60 may be a transparent conductive material such as indium-tin oxide (ITO), aluminum or gallium zinc oxide, or graphene. The minimum thickness of conductive strip 60 on pixels Pix may be in the range from 0.05 μm to 1,000 μm.

According to an embodiment, a metal grid may be formed above each transparent conductive strip 60 and in contact with transparent conductive strip 60, pixels Pix being located at the level of openings of the metal grid. This enables to improve the electric conduction without hindering the radiation emitted and received by pixels Pix.

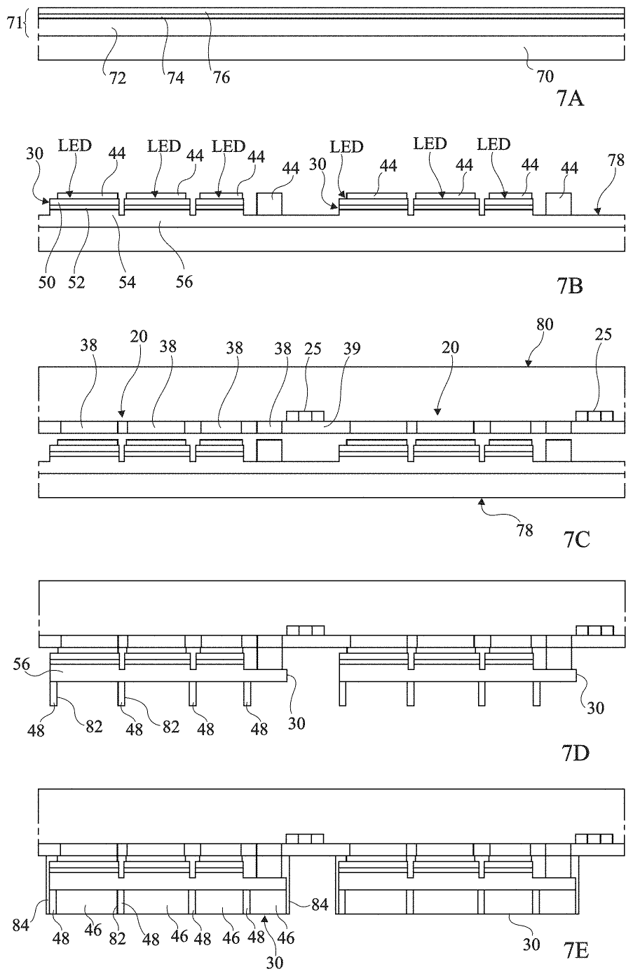

FIG. 6 is a side view of another more detailed embodiment of optoelectronic device 10. In this embodiment, optoelectronic device 10 comprises all the elements of the embodiment previously described in relation with FIG. 5 and further comprises an electrically-insulating layer 62 covering the sides of pixel Pix, particularly the sides of control and capture circuit 20 and the sides of each display circuit 30. The minimum thickness of insulating layer 62 may be in the range from 2 nm to 1 mm. Insulating layer 62 may be made of one of the materials previously described for insulating layer 39. Each conductive strip 60, in addition to covering the upper surface of each pixel Pix, may cover a portion of the insulating layer 62 of pixel Pix.

An advantage of the embodiments shown in FIGS. 5 and 6 is that they enable to decrease the number of electric connections towards the outside on the lower surface side 24 of the control and capture circuit 20 of each pixel Pix.

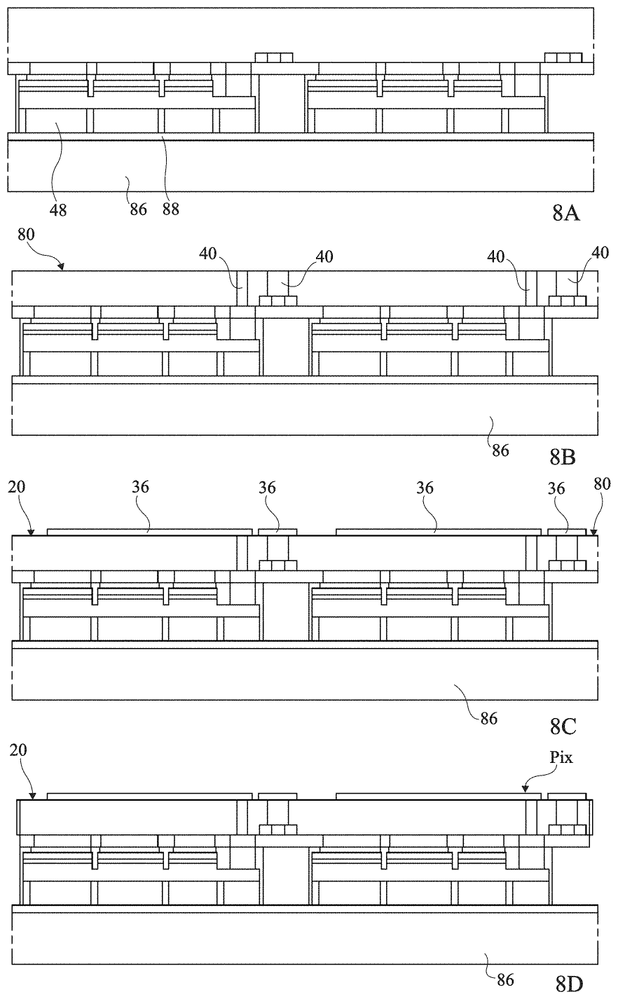

FIG. 7 shows partial simplified lateral cross-section views 7A to 7E of structures obtained at successive steps of an embodiment of a method of manufacturing the optoelectronic device 10 shown in FIG. 4.

View 7A shows the structure obtained after the forming on a support 70 of a stack 71 of semiconductor layers, comprising, from bottom to top in FIG. 7A, a semiconductor layer 72, an active layer 74, and a semiconductor layer 76. Semiconductor layer 72 may have the same composition as the previously-described semiconductor layers 54, 56. Active layer 74 may have the same composition as the previously-described active layer 52. Semiconductor layer 76 may have the same composition as the previously-described semiconductor layer 50. A seed layer may be provided between support 70 and semiconductor layer 72. Preferably, there is no seed layer between support 70 and semiconductor layer 72.

View 7B shows the structure obtained after the delimiting of the light-emitting diodes LED of display circuits 30 and the forming of conductive pads 44. Light-emitting diodes LED may be delimited by etching semiconductor layer 72, active layer 74, and semiconductor layer 76 to delimit semiconductor layer 54, active layer 52, and semiconductor layer 50, for each light-emitting diode LED of each optoelectronic circuit 30. The implemented etching may be a dry etching, for example, using a chlorine- and fluorine-based plasma, a reactive ion etching (RIE). The non-etched portion of semiconductor layer 72 forms the previously-described semiconductor layer 56. Conductive pads 44 may be obtained by depositing a conductive layer over the entire obtained structure and by removing the portion of the conductive layer outside of conductive pads 44. An optoelectronic circuit 78 comprising a plurality of copies, not completed yet, of display circuit 30, is obtained, two copies being shown in view 7B.

View 7C shows the structure obtained after the manufacturing of an optoelectronic circuit 80 comprising a plurality of copies, not fully completed, of the desired control and capture circuit 20, particularly by conventional steps of an integrated circuit manufacturing method, and just before the attaching of optoelectronic circuit 80 to optoelectronic circuit 78. The substrate of optoelectronic circuit 78 is thicker than the substrate of control and capture circuits 20 once completed. Each copy, not fully completed, of the desired control and capture circuit 20 however comprises the transistors, not shown, photosensors 25, conductive pads 38, and insulating layer 39. Further, optoelectronic circuit 78 does not comprise through conductive vias 40. The methods of assembling electronic circuit 80 to optoelectronic circuit 78 may comprise soldering or molecular bonding operations.

View 7D shows the structure obtained after the forming of walls 48 in support 70 and after the separation of display circuits 30. Walls 48 may be formed by etching openings 82 in support 70. Display circuits 30 may be separated by etching of semiconductor layer 56.

FIG. 7E shows the structure obtained after the forming of photoluminescent blocks 46 and the possible forming of insulating layers 84 on the sides of display circuits 30. Photoluminescent blocks 46 may be formed by filling of certain openings 82 with a colloidal dispersion of semiconductor nanocrystals in a bonding array, for example, by a so-called additive method, and possibly by obstructing certain openings 82 with resin. The so-called additive method may comprise the direct printing of the colloidal dispersion at the desired locations, for example, by inkjet printing, aerosol printing, microprinting, photogravure, silk-screening, flexography, spray coating, or drop casting. According to another embodiment, photoluminescent blocks 46 may be formed before the forming of walls 48.

FIG. 8 shows partial simplified lateral cross-section views 8A to 8D of structures obtained at subsequent successive steps of the manufacturing method previously-described in relation with FIG. 7.

View 8A shows the structure obtained after the attachment of the structure shown in view 7E, on the side of photoluminescent blocks 46, to a support 86, also called handle, by using a bonding material 88.

View 8B shows the structure obtained after having thinned the substrate of electronic circuit 80 on the side opposite to handle 86 and formed conductive vias 40 in the substrate.

View 8C shows the structure obtained after the forming of the conductive pads 36 of control and capture circuits 20, not completed yet, on electronic circuit 80 on the side opposite to handle 86.

View 8D shows the structure obtained after the separation of control and capture circuits 20 in electronic circuit 80, a single control and capture circuit being shown in view 8D. Pixels Pix are thus delimited while remaining attached to handle 86.

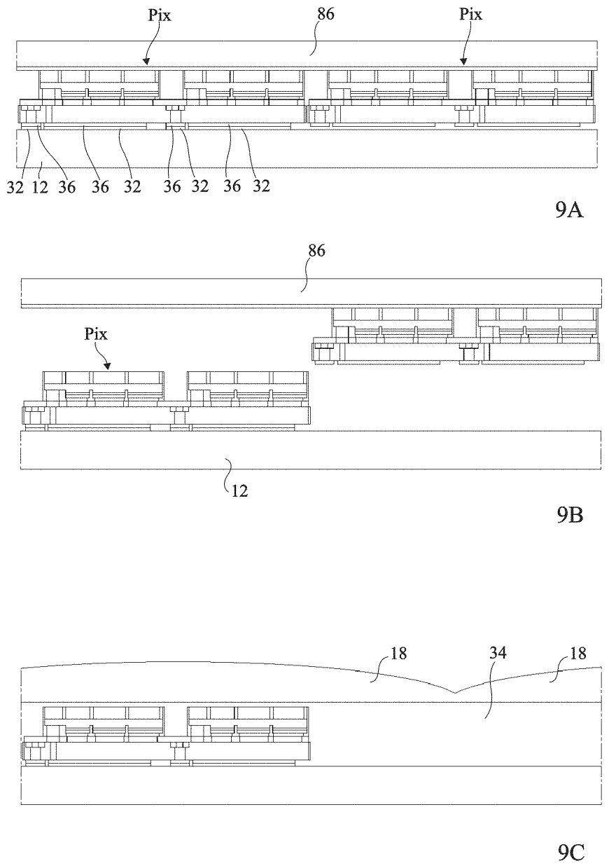

FIG. 9 shows partial simplified lateral cross-section views 9A to 9C of structures obtained at subsequent successive steps of the manufacturing method previously described in relation with FIG. 8.

View 9A shows the structure obtained after the attachment of some of display pixels Pix to support 12. In the present embodiment, two pixels attached to handle 86 have been shown and the electrodes 32 associated with a pixel Pix on support 12 have been shown. The pixels Pix which are not in contact with electrodes 32 are not attached to support 12. As an example, each pixel Pix may be attached to electrodes 32 by molecular bonding of conductive pads 36 to electrodes 32 or via a bonding material, particularly an electrically-conductive epoxy glue.

View 9B shows the structure obtained after the separation of handle 86 from the pixels Pix attached to support 12. Such a separation may be performed by laser ablation. The embodiment illustrated in views 9A and 9B enables to simultaneously attach a plurality of pixels Pix to support 12. As a variation, after the step illustrated in view 9B, pixels Pix may be separated from handle 86 and a “pick and place” method may be implemented, comprising separately placing each pixel Pix on support 12.

View 9C shows the structure obtained after the forming of encapsulation layer 34 and of microlenses 18. Encapsulation layer 34 may be deposited by chemical vapor deposition (CVD), plasma-enhanced chemical vapor deposition (PECVD), or cathode sputtering. Microlenses 18 may be formed by aligned lamination of films of microlenses after having planarized the wafer onto which the pixels have been transferred. An etching of transparent planarization resin, 3D printing, or the printing of patterns from a hard material may also be used.

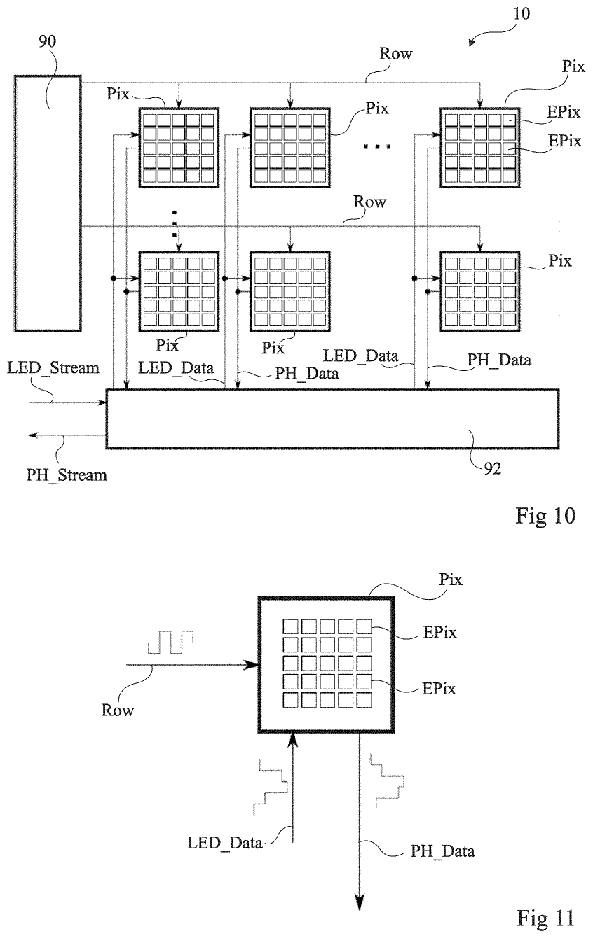

FIG. 10 is a diagram illustrating an embodiment of electric connections between the pixels Pix of the optoelectronic device 10 shown in FIGS. 1 and 2.

As previously described, each pixel Pix comprises an array of elementary pixels EPix, each elementary pixel EPix enabling to display and/or to capture a pixel of an image according to a viewpoint. The elementary pixels EPix of a same pixel Pix are associated with different viewpoints. Thereby, a complete image according to a given viewpoint, displayed or captured, may be reconstructed from each image pixel of this image according to this viewpoint, displayed or captured by each pixel Pix. As an example, in FIG. 10, each pixel Pix is shown as comprising an array of 5*5 elementary pixels EPix.

According to an embodiment, pixels Pix are arranged in M rows and N columns, M and N being integers, product M*N corresponding to the resolution desired for the images captured by device 10 and the images displayed by device 10, for example, 1920*1080 image pixels.

According to the present embodiment, device 10 comprises a row control circuit 90 and a column control circuit 92. Column control circuit 92 receives a stream of data LED_Stream representative of the intensities of the image pixels to be displayed by device 10 and delivers a stream of data PH_Stream representative of the intensities of the image pixels captured by device 10. For each row of pixels Pix, row control circuit 90 is capable of delivering a signal Row to each pixel Pix in the row. For each pixel column Pix, column control circuit 92 is capable of delivering a signal LED_Data to each pixel Pix of the column and of receiving a signal PH_Data delivered by each pixel Pix of the column.

According to an embodiment, the operation of optoelectronic device 10 comprises the successive selection of pixels Pix of each row by row control circuit 90 and, for each selected row and for each column, the transmission to the pixel of the column and of the selected row, via signal LED_Data, of data representative of the current and/or of the voltage to be supplied to each light-emitting diode of each elementary pixel EPix of the pixel of the column and of the selected row and the reception, via signal PH_Data, of data delivered by the pixel of the column and of the selected row and representative of the light intensity captured by each photodiode of each elementary pixel of the pixel of the column and of the selected row.

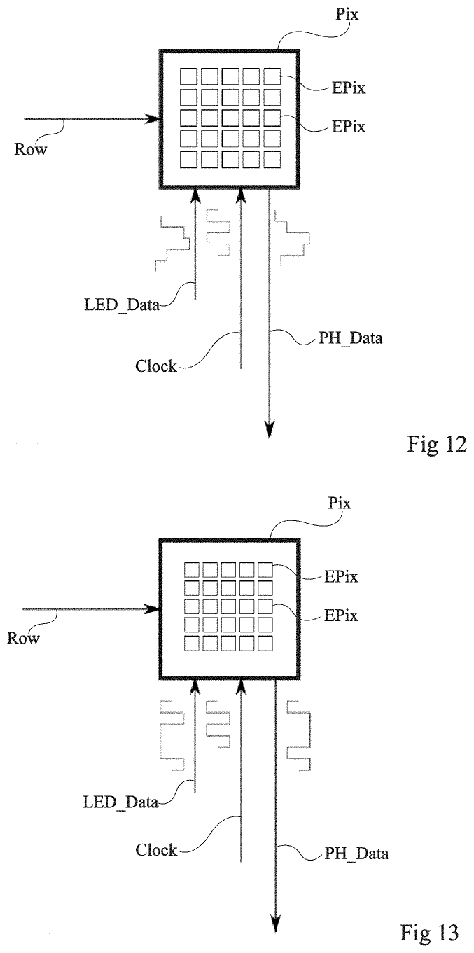

FIGS. 11 and 12 illustrate embodiment of a method of controlling a pixel of the optoelectronic device shown in FIG. 10. In these embodiments, each signal LED_Data and each signal PH_Data is an analog signal, for example, an analog signal with discrete values. As an example, for each column, each level of signal LED_Data is representative of the light intensity to be emitted by one of the light-emitting diodes of one of the elementary pixels EPix of the pixel Pix of the column and of the selected row. As an example, for each column, each level of signal PH_Data is representative of the light intensity captured by one of the photodiodes of one of the elementary pixels EPix of the pixel Pix of the column and of the selected row. In the embodiment illustrated in FIG. 11, signal Row may further play the role of a clock signal to rate the operation of pixel Pix. In the embodiment illustrated in FIG. 12, clock signal Clock is different from selection signal Row and, for each column, is transmitted to each pixel Pix of the column by column control circuit 92. An advantage of the embodiments illustrated in FIGS. 11 and 12 is that each pixel Pix needs to comprise neither digital-to-analog converters to control the light-emitting diodes of the elementary pixels EPix of pixel Pix, nor analog-to-digital converters to convert the signals delivered by the photodiodes of the elementary pixels EPix of pixel Pix.

FIG. 13 illustrates an embodiment of a method of controlling a pixel of the optoelectronic device shown in FIG. 10 where each signal LED_Data and each signal PH_Data is a digital signal. The transmission of signals LED_Data and PH_Data may be achieved over a serial link of SPI type (Serial Peripheral Interface) which allows the simultaneous transmission of signals in both directions. FIG. 13 shows a clock signal Clock different from selection signal Row which, for each column, is transmitted to each pixel Pix of the column by column control circuit 92. According to another embodiment, the transmission of signals LED_Data and PH_Data may implement self-synchronization data transmission protocols for example, the Manchester protocol. In this case, signal Clock may be absent.

FIG. 14 shows, in the form of a block diagram, an embodiment of a pixel Pix of the device shown in FIGS. 1 and 2 adapted to the case where signals LED_Data and PH_Data are digital signals.

Each pixel Pix comprises a register 94, for example, a shift register controlled by signal Clock, having the successive bits of signal LED_Data stored therein and a register 96, for example, a shift register controlled by signal Clock, which delivers the successive bits of signal PH_Data. For each elementary pixel EPix, pixel Pix comprises a circuit 98 (LED driver) for controlling the light-emitting diodes LED of the display circuit 30 of elementary pixel EPix. Each control circuit 98 comprises three memories 100 (Data latch) which receive data stored in register 94. Each control circuit 98 further comprises three digital-to-analog and control circuits 102 (DAC+driver) capable of delivering, from the binary data stored in memories 100, the analog signals R_out, G_out, and B_out for controlling light-emitting diodes LED. Further, for each elementary pixel EPix, pixel Pix comprises a circuit 104 (LS driver) for processing the signals R_sense, G_sense, B_sense delivered by the photodiodes PH of the photosensor 25 of elementary pixel Epix. Each processing circuit 104 comprises three analog-to-digital converters 106 (ADC) capable of supplying, from analog signals R_sense, G_sense, B_sense, digital data stored in three memories 108 (Data Latch). Each processing circuit 104 is further capable of delivering the digital data stored in memories 108 to register 96.

Each pixel Pix may further receive a signal sense_en and a signal disp_en. Signal sense_en enables to trigger the capture of an image and signal disp_en enables to generally trigger the turning-on and the turning-off of the screen. The signals are connected to all the pixels Pix. When signal disp_en is at logic level “1”, the image is displayed, and when signal disp_en is at logic level “0”, the screen is off. The loading of image N+1 can be performed during the display of image N and image N+1 will be displayed the next time that signal disp_en takes value “1”. Further, signal disp_en enables to turn off the screen during capture phases to avoid distorting the captured image. Signal sense_en further enables to control the time of capture of an image.

An advantage of the previously-described embodiments is that the number of connection terminals of each pixel Pix is decreased with respect to the number of connections which would be necessary to directly connect each elementary pixel EPix to column control circuit 92.

In the embodiment illustrated in FIG. 10, the transmission of signals LED_Data and PH_Data for each column is schematically shown by tracks which extend along the column from column control circuit 92 and which are connected to each pixel Pix of the column. It may however be difficult to ensure the integrity of the signals transmitted when the distance between certain pixels Pix and column control circuit 92 becomes too large.

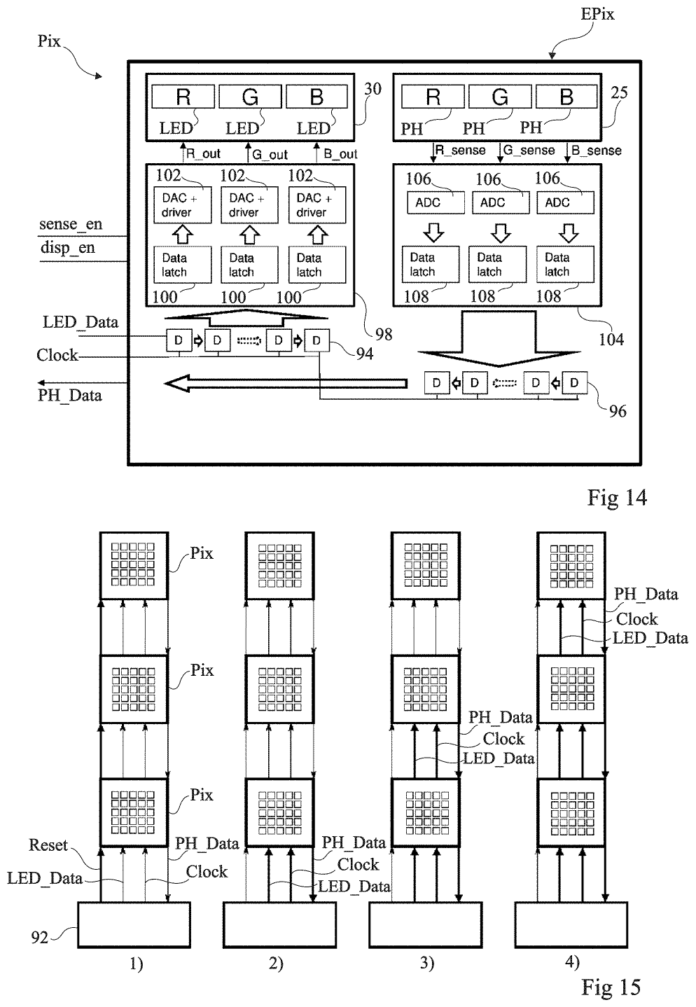

FIG. 15 illustrates a method of controlling an embodiment of optoelectronic device 10. FIG. 15 schematically shows a column of the optoelectronic device comprising three pixels Pix at four steps of the control method. Hereafter, the row of pixels Pix closest to column control circuit 92 is called first row and the row of pixels Pix most distant from column control circuit 92 is called last row. In the present embodiment, for each column, each pixel Pix of the column, except for the pixels Pix located at the ends of the column, is electrically connected to the two adjacent pixels of the column by a plurality of conductive tracks. Pixel Pix, located on the last row, is connected to the adjacent pixel Pix of the column and pixel Pix, located on the first row, is connected to column control circuit 92. In the present embodiment, for each column, the transmission of a signal from column control circuit 92 to a given pixel Pix in the column and the transmission of a signal from the given pixel Pix to column control circuit 92 is performed by successively passing through each pixel Pix located between column control circuit 92 and the given pixel Pix, each of the intermediate pixels playing the role of a transmission relay. This enables to decrease the maximum distance between an emitter and a receiver.

FIG. 15 shows four links between two adjacent pixels Pix and between the pixel Pix of the first row and column control circuit 92. Three links are used for the transmission of the previously-described signals PH_Data, LED_Data, and Clock and one link is used for the transmission of a signal Reset. FIG. 15 shows with a thick line an active link, that is, having a useful signal transiting over it, and, with a thin line, an inactive link. Signal LED_Data may correspond to a frame which contains all the data necessary for the display of the image pixels desired for the elementary pixels of the pixels of all the rows of the optoelectronic device. As an example, the frame successively comprises the data relative to the elementary pixels of the pixel Pix of the last row, of the penultimate row, etc. all the way to the first row.

An embodiment of data transmission between column control circuit 92 and pixels Pix comprises the following steps:
1) a pulse of signal Reset is simultaneously transmitted to all the pixels Pix of all the columns;
2) signals Clock and LED_Data are simultaneously transmitted by column control circuit 92 to each pixel of the first row. Each pixel of the first row further transmits the signal PH_Data that it has generated to column control circuit 92;
3) for each column, signals Clock and LED_Data are transmitted via the first pixel of the first row to the pixel of the second row. Conversely, the pixel of the second row transmits the signal PH_Data that it has generated to column control circuit 92 via the first pixel of the first row; and
4) signals Clock and LED_Data thus move on from row to row all the way to the last row. In parallel, each pixel, which starts receiving signal LED_Data, transmits the signal PH_Data that it has generated, the signal being relayed, pixel after pixel, all the way to column control circuit 92.

Various embodiments and variations have been described. It will be understood by those skilled in the art that these various embodiments and variations may be combined, and other variations will occur to those skilled in the art. In particular, the insulating layers 62 previously described for the embodiment of the optoelectronic device shown in FIG. 6 may also be provided for the embodiments of the optoelectronic device shown in FIGS. 4 and 5.

Finally, the practical implementation of the described embodiments and variations is within the abilities of those skilled in the art based on the functional indications given hereabove.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An optoelectronic multiscopic image display and/or capture device, comprising a support, an array of optoelectronic circuits resting on the support, and lenses covering the optoelectronic circuits, each optoelectronic circuit comprising a number N of photosensors capable of capturing a pixel or pixels of an image of a scene according to different viewpoints and/or the number of N of display circuits capable of displaying a pixel or pixels of an image of a scene according to the different viewpoints, N being a natural number greater than or equal to 3, wherein each optoelectronic circuit comprises the number N of photosensors capable of capturing a pixel of an image of a scene according to different viewpoints and the number N of display circuits capable of displaying a pixel of an image of a scene according to different viewpoints.

2. The device of claim 1, wherein the photosensors and/or the display circuits are arranged in an array.

3. The device of claim 1, wherein each optoelectronic circuit comprises the N display circuits and an integrated circuit attached to the support, the N display circuits being attached to the integrated circuit, on the side of the integrated circuit opposite to the support.

4. The device of claim 3, wherein the integrated circuit comprises the N photosensors.

5. The device of claim 1, wherein each display circuit comprises at least one light-emitting diode.

6. The device of claim 1, wherein each photosensor comprises at least one photodiode.

7. The device of claim 1, wherein each optoelectronic circuit is connected to less than 10 electrically-conductive tracks.

8. A method of manufacturing the optoelectronic device of claim 1.

9. The method of claim 8, wherein each optoelectronic circuit comprises the N display circuits and an integrated circuit attached to the support, the N display circuits being attached to the integrated circuit, on the side of the integrated circuit opposite to the support, the method comprising the successive steps of:
a. forming a first wafer comprising a plurality of copies of the integrated circuit and forming a second wafer comprising a plurality of copies of the display circuit;
b. attaching the second wafer to the first wafer;
c. separating the display circuits in the second wafer; and
d. separating the integrated circuits in the first wafer.

10. The method of claim 9, wherein step d) is preceded by a step e) of attaching the display circuits to a handle.

11. The method of claim 10 comprising, between steps e) and d), a step of thinning the first wafer.

12. A use of the optoelectronic device of claim 1, comprising the provision by each optoelectronic circuit of first data representative of the image pixels captured by the N photosensors of said optoelectronic circuit and/or the provision to each optoelectronic circuit of second data representative of the pixels of the image to be displayed by the N display circuits of said optoelectronic circuit

13. The use of claim 12, wherein the optoelectronic circuits are arranged in rows and in columns and wherein, for each column, at least one of the optoelectronic circuits of the column is capable of receiving the signals and of at least partly transmitting said signals to another optoelectronic circuit of the column.
